(19) United States
(12) Patent Application Publication
(10) Pub. No.: US 2025/0250663 A1
(43) Pub. Date: Aug. 7, 2025

(54) DEPOSITION MASK AND DEPOSITION EQUIPMENT INCLUDING THE SAME

(71) Applicant: Samsung Display Co., LTD., Yongin-si (KR)

(72) Inventors: Seung Hun KIM, Yongin-si (KR); Young Jin SONG, Yongin-si (KR)

(73) Assignee: Samsung Display Co., LTD., Yongin-si (KR)

(21) Appl. No.: 18/933,462

(22) Filed: Oct. 31, 2024

(30) Foreign Application Priority Data
Feb. 6, 2024 (KR) 10-2024-0017925

(51) Int. Cl. C23C 14/04

(52) U.S. Cl. CPC C23C 14/046

(57) ABSTRACT

Provided are a deposition mask and a deposition equipment including the same. A deposition mask includes a substrate comprising cell areas and a mask frame area excluding the cell areas, and a mask membrane disposed in each of the cell areas. A cross-sectional structure of the mask membrane includes a multilayer in which inorganic layers and metal layers are alternately stacked each other.

### CROSS-REFERENCE TO RELATED APPLICATION(S)

This application claims priority to and benefits of Korean Patent Application No. 10-2024-0017925 under 35 U.S.C. § 119, filed on Feb. 6, 2024, in the Korean Intellectual Property Office, the entire contents of which are incorporated herein by reference.

### BACKGROUND

### 1. Technical Field

Embodiments relate to a deposition mask and a deposition equipment including the same.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device provides an augmented reality (hereinafter, referred to as “AR”) screen or a virtual reality (hereinafter, referred to as “VR”) screen to a user.

The wearable devices such as the HMD device or the AR glasses require a display specification of at least 2,000 PPI (pixels per inch) so that a user may use it for a long time without dizziness. To this end, organic light emitting diode on silicon (OLEDoS) technology that is a high-resolution small organic light emitting display device is emerging. The organic light emitting diode on silicon (OLEDoS) is technology for disposing an organic light emitting diode (OLED) on a semiconductor wafer substrate on which a complementary metal oxide semiconductor (CMOS) is disposed.

In order to manufacture a display panel of high-resolution of 2,000 PPI, a high-resolution deposition mask is required. To this end, silicon masks that can form masks with the precision of semiconductor processes are being researched and developed. as a silicon mask.

The silicon mask may be a mask that deposits an inorganic layer pattern on a silicon substrate and allows the inorganic layer pattern to function as a mask membrane. Such silicon masks may have a problem in that damage occurs in case that cleaning the mask due to the thin mask membrane.

The silicon mask may be a mask that forms a plating film on a silicon substrate and forms a mask membrane by a patterning of the plating film. Although such silicon masks have high mechanical strength and are readily cleaned, since the mask membrane made of a plating film has a high coefficient of thermal expansion (CTE), there is a high possibility of misalignment with a backplane substrate, which is a substrate to be deposited, and a possibility of deposition defects due to deviation in the thickness of the plating film during the process.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a deposition mask that has a high mechanical strength and are readily cleaned, and capable of increasing the accuracy of the alignment by reducing coefficient of thermal expansion (CTE), and a deposition equipment including the same.

According to embodiments, a deposition mask may include a substrate comprising a plurality of cell areas and a mask frame area excluding the plurality of cell areas, and a mask membrane disposed in each of the plurality of cell areas. A cross-sectional structure of the mask membrane may include a multilayer in which a plurality of inorganic layers and a plurality of metal layers are alternately stacked each other.

A cross-sectional structure of the mask membrane may include a first metal layer, a first inorganic layer disposed on the first metal layer, a second metal layer disposed on the first inorganic layer, a second inorganic layer disposed on the second metal layer, a third metal layer disposed on the second inorganic layer, and a third inorganic layer disposed on the third metal layer.

When viewed from a cross-section in which the mask membrane is cut, the first metal layer may be disposed on a lowermost layer of the mask membrane and the third inorganic layer may be disposed on an uppermost layer of the mask membrane.

The first inorganic layer may include at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

The second inorganic layer may include at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

The third inorganic layer may include at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

The materials of the first inorganic layer, the second inorganic layer and the third inorganic layer may be same.

The materials of the first inorganic layer, the second inorganic layer and the third inorganic layer may be different from each other.

The first metal layer may include at least one material of copper (Cu), nickel (Ni), aluminum (Al), tungsten (W), molybdenum (Mo), titanium (Ti), and invar.

The second metal layer may include at least one material of copper (Cu), nickel (Ni), aluminum (Al), tungsten (W), molybdenum (Mo), titanium (Ti), and invar.

The third metal layer may include at least one material of copper (Cu), nickel (Ni), aluminum (Al), tungsten (W), molybdenum (Mo), titanium (Ti), and invar.

The materials of the first metal layer, the second metal layer and the third metal layer may be same.

The materials of the first metal layer, the second metal layer and the third metal layer may be different from each other.

According to embodiments, a deposition mask may include a substrate comprising a plurality of cell areas and a mask frame area excluding the plurality of cell areas, and a mask membrane disposed in each of the plurality of cell areas. The mask membrane may include a mixed layer in which at least one inorganic layer and at least one metal layer are mixed.

The mixed layer may include a mixed material in which at least one inorganic material of silicon (Si), silicon nitride (SiNₓ), silicon oxynitride (SiON), silicon oxide (SiOₓ), titanium oxide (TiOₓ), amorphous silicon (a-Si), and aluminum oxide, and at least one metal material of copper (Cu), nickel (Ni), aluminum (Al), tungsten (W), molybdenum (Mo), titanium (Ti), and invar are mixed.

The substrate may be a silicon substrate.

According to embodiments, a deposition equipment may include a chamber; a deposition source disposed in the chamber; a mask disposed between a first substrate and the deposition source in the chamber; and a mask support disposed between the deposition source and the mask to support at least a portion of the mask. The mask may include a second substrate including a plurality of cell areas and a mask frame excluding the plurality of cell areas, and a mask membrane disposed in each of the plurality of cell areas. A cross-sectional structure of the mask membrane may include a multilayer in which a plurality of inorganic layers and a plurality of metal layers are alternately stacked each other.

The cross-sectional structure of the mask membrane may include a first metal layer, a first inorganic layer disposed on the first metal layer, a second metal layer disposed on the first inorganic layer, a second inorganic layer disposed on the second metal layer, a third metal layer disposed on the second inorganic layer, and a third inorganic layer disposed on the third metal layer.

When viewed from a cross-section in which the mask membrane is cut, the first metal layer may be disposed on a lowermost layer of the mask membrane and the third inorganic layer may be disposed on an uppermost layer of the mask membrane.

The first inorganic layer, the second inorganic layer and the third inorganic layer may include at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ). The first metal layer, the second metal layer and the third metal layer may include at least one material from copper (Cu), nickel (Ni), aluminum (Al), tungsten (W), molybdenum (Mo), titanium (Ti), and invar.

According to embodiments, it is possible for a deposition mask and a deposition equipment including the same to have high mechanical strength and be readily cleaned, and increase the accuracy of the alignment by reducing a coefficient of thermal expansion (CTE).

According to embodiments, it is also possible for a deposition mask and a deposition equipment to reduce deposition defects due to deviation in the thickness of the mask.

### BRIEF DESCRIPTION OF THE DRAWINGS

The accompanying drawings, which are included to provide a further understanding of the disclosure, illustrate embodiments in which:

FIG. 1 is an exploded perspective view showing a display device according to one embodiment;

FIG. 2 is a block diagram illustrating a display device according to one embodiment;

FIG. 3 is a schematic diagram of an equivalent circuit of a first sub-pixel according to one embodiment;

FIG. 4 is a plan diagram illustrating an example of a display panel according to one embodiment;

FIGS. 5 and 6 are plan diagrams illustrating embodiments of the display area of FIG. 4;

FIG. 7 is a schematic cross-sectional view illustrating an example of a display panel taken along line I1-I1′ of FIG. 5;

FIG. 8 is a schematic perspective view illustrating a head mounted display according to one embodiment;

FIG. 9 is an exploded perspective view illustrating an example of the head mounted display of FIG. 8;

FIG. 10 is a schematic perspective view illustrating a head mounted display according to one embodiment;

FIG. 11 is a schematic perspective view of a mask according to one embodiment;

FIG. 12 is a schematic plan view of a mask according to one embodiment;

FIG. 13 is a configuration view of a deposition equipment according to one embodiment;

FIGS. 14 and 15 are drawings illustrating stacked structures of a mask membrane according to one embodiment;

FIGS. 16 to 20 are process cross-sectional views illustrating a method for manufacturing a mask according to one embodiment; and

FIGS. 21 to 25 are diagrams illustrating a method of forming a mask membrane as a mixed layer according to one embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on another layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The expression “not overlap” may include meaning such as “apart from” or “set aside from” or “offset from” and any other suitable equivalents as would be appreciated and understood by those of ordinary skill in the art.

The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements disposed therebetween.

It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, ±20%, ±10%, ±5% of the stated value.

In the description, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the description, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the description.

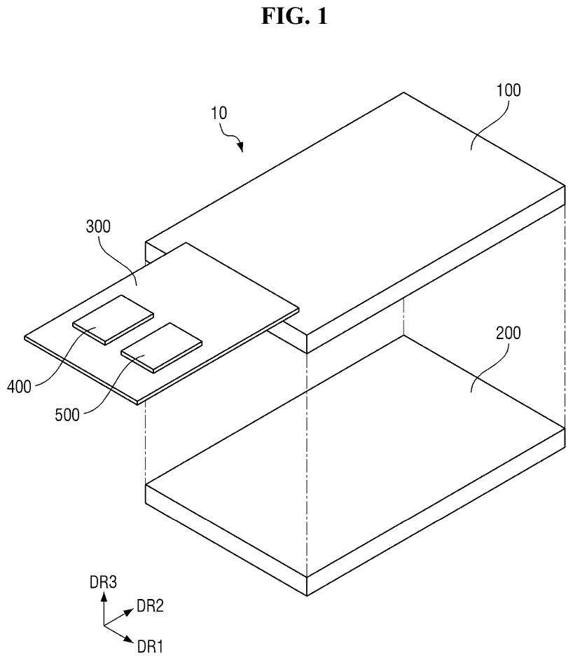

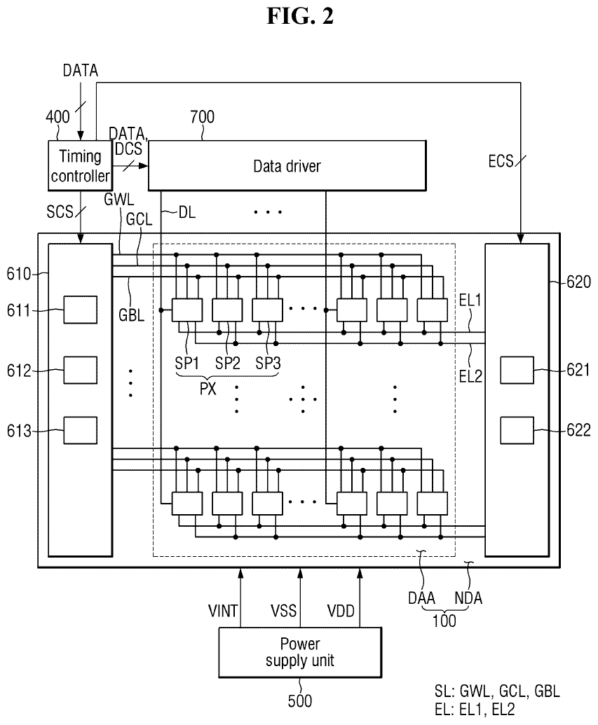

FIG. 1 is an exploded perspective view showing a display device according to one embodiment. FIG. 2 is a block diagram illustrating a display device according to one embodiment.

Referring to FIGS. 1 and 2, a display device 10 according to one embodiment is a device displaying a moving image or a still image. The display device 10 according to one embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like within the spirit and the scope of the disclosure. For example, the display device 10 according to one embodiment may be applied as a display unit of a television, a laptop, a monitor, a billboard, or an Internet-of-Things (IoT) terminal. By way of example, the display device 10 according to one embodiment may be applied to a smart watch, a watch phone, a head mounted display (HMD) for implementing virtual reality and augmented reality, and the like within the spirit and the scope of the disclosure.

The display device 10 according to one embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selectable curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment is not limited thereto.

The display panel 100 may include a display area DAA displaying an image and a non-display area NDA not displaying an image as shown in FIG. 2.

The display area DAA may include a plurality of pixels PX, a plurality of scan lines SL, a plurality of emission control lines EL, and a plurality of data lines DL.

The plurality of pixels PX may be arranged or disposed in a matrix form in the first direction DR1 and the second direction DR2. The plurality of scan lines SL and the plurality of emission control lines EL may extend in the first direction DR1, while being disposed in the second direction DR2. The plurality of data lines DL may extend in the second direction DR2, while being disposed in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

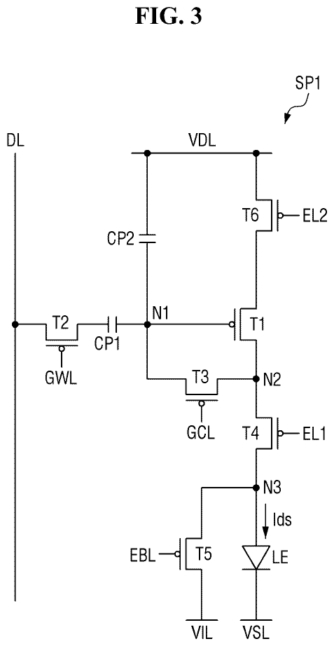

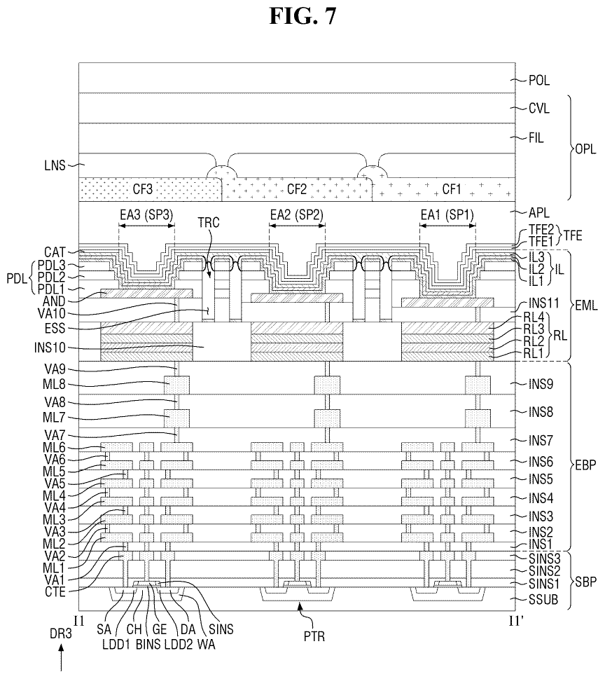

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of a data driver 700 may be formed of complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light emitting element according to the data voltage.

The non-display area NDA may include a scan driver 610, an emission driver 620, and the data driver 700.

The scan driver 610 may include a plurality of scan transistors, and the emission driver 620 may include a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS. Although it is illustrated in FIG. 2 that the scan driver 610 is disposed on the left side of the display area DAA and the emission driver 620 is disposed on the right side of the display area DAA, the embodiment is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

The emission driver 620 may include a first emission control driver 621 and a second emission control driver 622. Each of the first emission control driver 621 and the second emission control driver 622 may receive the emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on one surface or a surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

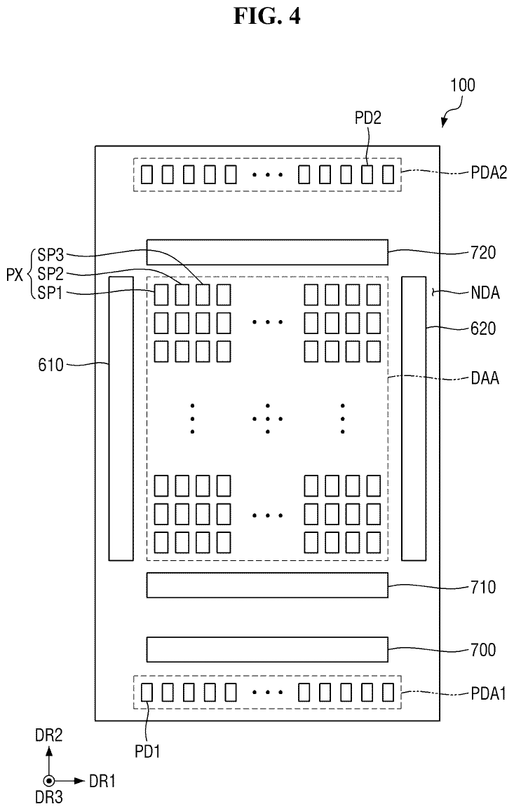

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface or a surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

By way of example, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

FIG. 3 is a schematic diagram of an equivalent circuit of a first sub-pixel according to one embodiment.

Referring to FIG. 3, the first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 may include a gate electrode connected to a first node N1, a source electrode connected to the drain electrode of the sixth transistor T6, and a drain electrode connected to a second node N2.

The second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

The third transistor T3 may be disposed between the first node N1 and the second node N2. The third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the embodiment is not limited thereto. Each of the first to sixth transistors T1 to T6 may be an N-type MOSFET. By way of example, some of the first to sixth transistors T1 to T6 may be P-type MOSFETs, and each of the remaining transistors may be an N-type MOSFET.

Although it is illustrated in FIG. 3 that the first sub-pixel SP1 may include six transistors T1 to T6 and two capacitors CP1 and CP2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 may be omitted in the specification.

FIG. 4 is a plan diagram illustrating an example of a display panel according to one embodiment.

Referring to FIG. 4, the display area DAA of the display panel 100 according to one embodiment may include the plurality of pixels PX arranged or disposed in a matrix form. The non-display area NDA of the display panel 100 according to one embodiment may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side or a side of the display area DAA in the first direction DR1, and the emission driver 620 may be disposed on the other side of the display area DAA in the first direction DR1. For example, the scan driver 610 may be disposed on the left side of the display area DAA, and the emission driver 620 may be disposed on the right side of the display area DAA. However, the embodiment is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side or a side of the display area DAA in the second direction DR2.

The first pad portion PDA1 may be disposed outside the data driver 700 in the second direction DR2. For example, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side or a side of the display area DAA in the second direction DR2. For example, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. For example, the second distribution circuit 720 may be disposed on the upper side of the display area DAA.

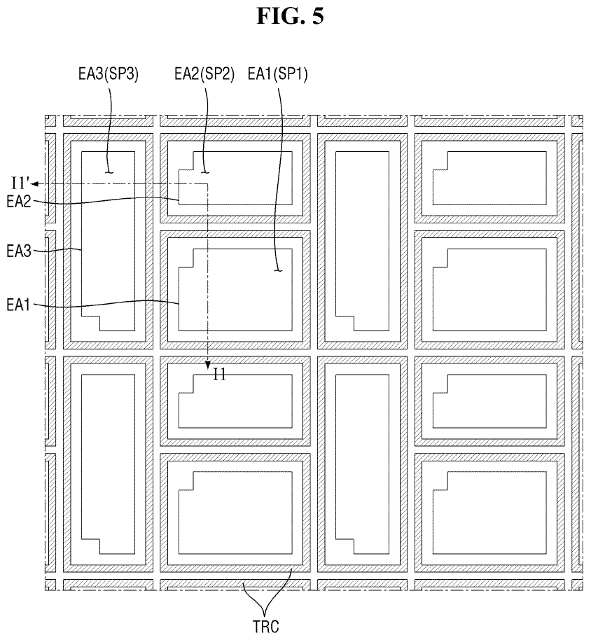

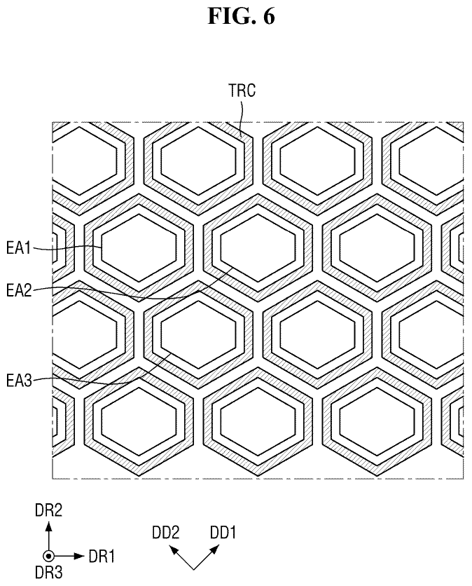

FIGS. 5 and 6 are plan diagrams illustrating embodiments of the display area of FIG. 4.

Referring to FIGS. 5 and 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in plan view.

The maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2, and the third emission area EA3 may have, in plan view, a hexagonal shape formed of six straight lines as shown in FIGS. 5 and 6, but the embodiment is not limited thereto. The first emission area EA1, the second emission area EA2, and the third emission area EA3 may have a polygonal shape other than a hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. The second emission area EA2 and the third emission area EA3 may be adjacent to each other in the second direction DR2. The area of the first emission area EA1, the area of the second emission area EA2, and the area of the third emission area EA3 may be different.

By way of example, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit first light, the second emission area EA2 may emit second light, and the third emission area EA3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in a range of about 370 nm to about 460 nm, the green wavelength band may be a wavelength band of light whose main peak wavelength is in a range of about 480 nm to about 560 nm, and the red wavelength band may be a wavelength band of light whose main peak wavelength is in a range of about 600 nm to about 750 nm.

In FIGS. 5 and 6 that each of the plurality of pixels PX may include three emission areas EA1, EA2, and EA3, but the embodiment is not limited thereto. For example, each of the plurality of pixels PX may include four emission areas.

The plan of the emission areas of the plurality of pixels PX is not limited to that illustrated in FIGS. 5 and 6. For example, the emission areas of the plurality of pixels PX may be disposed in a stripe structure in which the emission areas are arranged or disposed in the first direction DR1, a PENTILE™ structure in which the emission areas are arranged or disposed in a diamond shape, or a hexagonal structure in which the emission areas having, in plan view, a hexagonal shape are arranged or disposed side by side as shown in FIG. 6.

FIG. 7 is a schematic cross-sectional view illustrating an example of a display panel taken along line I1-I1′ of FIG. 5.

Referring to FIG. 7, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, in case that the first type impurity is a p-type impurity, the second type impurity may be an n-type impurity. By way of example, in case that the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side or a side of the gate electrode GE, and the drain region DA may be disposed on the other side of the gate electrode GE.

Each of the plurality of well regions WA further may include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be prevented.

A first semiconductor insulating layer SINS1 may be disposed on the semiconductor substrate SSUB. The first semiconductor insulating layer SINS1 may be formed of silicon carbonitride (SiCN) or a silicon oxide (SiOₓ)-based inorganic layer, but the embodiment is not limited thereto.

A second semiconductor insulating layer SINS2 may be disposed on the first semiconductor insulating layer SINS1. The second semiconductor insulating layer SINS2 may be formed of a silicon oxide (SiOₓ)-based inorganic layer, but the embodiment is not limited thereto.

The plurality of contact terminals CTE may be disposed on the second semiconductor insulating layer SINS2. Each of the plurality of contact terminals CTE may be connected to any one of the gate electrode GE, the source region SA, and the drain region DA of each of the pixel transistors PTR through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be disposed on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOₓ)-based inorganic layer, but the embodiment is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of insulating layers INS1 to INS9. The light emitting element backplane EBP may include a plurality of insulating layers INS1 to INS11 disposed between the first to eighth conductive layers ML1 to ML8.

The first to eighth conductive layers ML1 to ML8 serve to connect the plurality of contact terminals CTE exposed from the semiconductor backplane SBP to thereby implement the circuit of the first sub-pixel SP1 shown in FIG. 4. For example, the first to sixth transistors T1 to T6 are formed on the semiconductor backplane SBP, and the connection of the first to sixth transistors T1 to T6 and the first and second capacitors CP1 and CP2 is accomplished through the first to eighth conductive layers ML1 to ML8. The connection between the drain region corresponding to the drain electrode of the fourth transistor T4, the source region corresponding to the source electrode of the fifth transistor T5, and the first electrode of the light emitting element LE is also accomplished through the first to eighth conductive layers ML1 to ML8.

The first insulating layer INS1 may be disposed on the semiconductor backplane SBP. Each of the first vias VA1 may penetrate the first insulating layer INS1 to be connected to the contact terminal CTE exposed from the semiconductor backplane SBP. Each of the first conductive layers ML1 may be disposed on the first insulating layer INS1 and may be connected to the first via VA1.

The second insulating layer INS2 may be disposed on the first insulating layer INS1 and the first conductive layers ML1. Each of the second vias VA2 may penetrate the second insulating layer INS2 and be connected to the exposed first conductive layer ML1. Each of the second conductive layers ML2 may be disposed on the second insulating layer INS2 and may be connected to the second via VA2.

The third insulating layer INS3 may be disposed on the second insulating layer INS2 and the second conductive layers ML2. Each of the third vias VA3 may penetrate the third insulating layer INS3 and be connected to the exposed second conductive layer ML2. Each of the third conductive layers ML3 may be disposed on the third insulating layer INS3 and may be connected to the third via VA3.

A fourth insulating layer INS4 may be disposed on the third insulating layer INS3 and the third conductive layers ML3. Each of the fourth vias VA4 may penetrate the fourth insulating layer INS4 and be connected to the exposed third conductive layer ML3. Each of the fourth conductive layers ML4 may be disposed on the fourth insulating layer INS4 and may be connected to the fourth via VA4.

A fifth insulating layer INS5 may be disposed on the fourth insulating layer INS4 and the fourth conductive layers ML4. Each of the fifth vias VA5 may penetrate the fifth insulating layer INS5 and be connected to the exposed fourth conductive layer ML4. Each of the fifth conductive layers ML5 may be disposed on the fifth insulating layer INS5 and may be connected to the fifth via VA5.

A sixth insulating layer INS6 may be disposed on the fifth insulating layer INS5 and the fifth conductive layers ML5. Each of the sixth vias VA6 may penetrate the sixth insulating layer INS6 and be connected to the exposed fifth conductive layer ML5. Each of the sixth conductive layers ML6 may be disposed on the sixth insulating layer INS6 and may be connected to the sixth via VA6.

A seventh insulating layer INS7 may be disposed on the sixth insulating layer INS6 and the sixth conductive layers ML6. Each of the seventh vias VA7 may penetrate the seventh insulating layer INS7 and be connected to the exposed sixth conductive layer ML6. Each of the seventh conductive layers ML7 may be disposed on the seventh insulating layer INS7 and may be connected to the seventh via VA7.

An eighth insulating layer INS8 may be disposed on the seventh insulating layer INS7 and the seventh conductive layers ML7. Each of the eighth vias VA8 may penetrate the eighth insulating layer INS8 and be connected to the exposed seventh conductive layer ML7. Each of the eighth conductive layers ML8 may be disposed on the eighth insulating layer INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating layers INS1 to INS8 may be formed of a silicon oxide (SiOx)-based inorganic layer, but the embodiment is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be about 1360 Å, the thickness of each of the second conductive layer ML2, the third conductive layer ML3, the fourth conductive layer ML4, the fifth conductive layer ML5, and the sixth conductive layer ML6 may be about 1440 Å; and the thickness of each of the first via VA1, the second via VA2, the third via VA3, the fourth via VA4, the fifth via VA5, and the sixth via VA6 may be about 1150 Å.

The thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be about 9000 Å. The thickness of each of the seventh via VA7 and the eighth via VA8 may be about 6000 Å.

The ninth insulating layer INS9 may be disposed on the eighth insulating layer INS8 and the eighth conductive layer ML8. The ninth insulating layer INS9 may be formed of a silicon oxide (SiOₓ)-based inorganic layer, but the embodiment is not limited thereto.

Each of the ninth vias VA9 may penetrate the ninth insulating layer INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be about 16500 Å.

The display element layer EML may be disposed on the light emitting element backplane EBP. The display element layer EML may include light emitting elements LE each including a reflective electrode layer RL, tenth and eleventh insulating layers INS10 and INS11, a tenth via VA10, the first electrode AND, a light emitting stack IL, and a second electrode CAT; a pixel defining layer PDL; and a plurality of trenches TRC.

The reflective electrode layer RL may be disposed on the ninth insulating layer INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

Each of the fourth reflective electrodes RL4 may be disposed on the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be about 100 Å, and the thickness of the second reflective electrode RL2 may be about 850 Å.

The tenth insulating layer INS10 may be disposed on the ninth insulating layer INS9. The tenth insulating layer INS10 may be disposed between the reflective electrode layers RL adjacent to each other in a horizontal direction. The tenth insulating layer INS10 may be disposed on the reflective electrode layer RL in the third sub-pixel SP3. The tenth insulating layer INS10 may be formed of a silicon oxide (SiOₓ)-based inorganic layer, but the embodiment is not limited thereto.

The eleventh insulating layer INS11 may be disposed on the tenth insulating layer INS10 and the reflective electrode layer RL. The eleventh insulating layer INS11 may be formed of a silicon oxide (SiOₓ)-based inorganic layer, but the embodiment is not limited thereto. The tenth insulating layer INS10 and the eleventh insulating layer INS11 may be an optical auxiliary layer through which light reflected by the reflective electrode layer RL passes, among light emitted from the light emitting elements LE.

In order to match the resonance distance of the light emitted from the light emitting elements LE in at least one of the first sub-pixel SP1, the second sub-pixel SP2, or the third sub-pixel SP3, the tenth insulating layer INS10 and the eleventh insulating layer INS11 may not be disposed under or below the first electrode AND of the first sub-pixel SP1. The first electrode AND of the first sub-pixel SP1 may be directly disposed on the reflective electrode layer RL. The eleventh insulating layer INS11 may be disposed under or below the first electrode AND of the second sub-pixel SP2. The tenth insulating layer INS10 and the eleventh insulating layer INS11 may be disposed under or below the first electrode AND of the third sub-pixel SP3.

In summary, the distance between the first electrode AND and the reflective electrode layer RL may be different in the first sub-pixel SP1, the second sub-pixel SP2, and the third sub-pixel SP3. For example, in order to adjust the distance from the reflective electrode layer RL to the second electrode CAT according to the main wavelength of the light emitted from each of the first sub-pixel SP1, the second sub-pixel SP2, and the third sub-pixel SP3, the presence or absence of the tenth insulating layer INS10 and the eleventh insulating layer INS11 may be set in each of the first sub-pixel SP1, the second sub-pixel SP2, and the third sub-pixel SP3. For example, it is illustrated in FIG. 7 that the distance between the first electrode AND and the reflective electrode layer RL in the third sub-pixel SP3 is larger than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 is larger than the distance between the first electrode AND and the reflective electrode layer RL in the first sub-pixel SP1, but the specification is not limited thereto.

Although the tenth insulating layer INS10 and the eleventh insulating layer INS11 are illustrated in the embodiment, a twelfth insulating layer disposed under or below the first electrode AND of the first sub-pixel SP1 may be added. In this case, the eleventh insulating layer INS11 and the twelfth insulating layer may be disposed under or below the first electrode AND of the second sub-pixel SP2, and the tenth insulating layer INS10, the eleventh insulating layer INS11, and the twelfth insulating layer may be disposed under or below the first electrode AND of the third sub-pixel SP3.

Each of the tenth vias VA10 may penetrate the tenth insulating layer INS10 and/or the eleventh insulating layer INS11 in the second sub-pixel SP2 and the third sub-pixel SP3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be smaller than the thickness of the tenth via VA10 in the third sub-pixel SP3.

The first electrode AND of each of the light emitting elements LE may be disposed on the tenth insulating layer INS10 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining layer PDL may be disposed on a portion of the first electrode AND of each of the light emitting elements LE. The pixel defining layer PDL may cover the edge of the first electrode AND of each of the light emitting elements LE. The pixel defining layer PDL may serve to partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining layer PDL may include first to third pixel defining layers PDL1, PDL2, and PDL3. The first pixel defining layer PDL1 may be disposed on the edge of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOₓ)-based inorganic layer, but the embodiment is not limited thereto. The first pixel defining layer PDL1, the second pixel defining layer PDL2, and the third pixel defining layer PDL3 may each have a thickness of about 500 Å.

In case that the first pixel defining layer PDL1, the second pixel defining layer PDL2, and the third pixel defining layer PDL3 are formed as one pixel defining layer, the height of the one pixel defining layer increases, so that a first encapsulation inorganic layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic layer TFE1 from being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. Furthermore, each of the plurality of trenches TRC may penetrate the eleventh insulating layer INS11. The tenth insulating layer INS10 may be partially recessed at each of the plurality of trenches TRC.

At least one trench TRC may be disposed between adjacent sub-pixels SP1, SP2, and SP3. Although FIG. 7 illustrates that two trenches TRC are disposed between adjacent sub-pixels SP1, SP2, and SP3, the embodiment is not limited thereto.

The light emitting stack IL may include a plurality of intermediate layers. FIG. 7 illustrates that the light emitting stack IL has a three-tandem structure including the first stack layer IL1, the second stack layer IL2, and the third stack layer IL3, but the embodiment is not limited thereto. For example, the light emitting stack IL may have a two-tandem structure including two intermediate layers.

In the three-tandem structure, the light emitting stack IL may have a tandem structure including a plurality of stack layers IL1, IL2, and IL3 that emit different lights. For example, the light emitting stack IL may include the first stack layer IL1 that emits first light, the second stack layer IL2 that emits third light, and the third stack layer IL3 that emits second light. The first stack layer IL1, the second stack layer IL2, and the third stack layer IL3 may be sequentially stacked each other.

The first stack layer IL1 may have a structure in which a first hole transport layer, a first organic light emitting layer that emits first light, and a first electron transport layer may be sequentially stacked each other. The second stack layer IL2 may have a structure in which a second hole transport layer, a second organic light emitting layer that emits third light, and a second electron transport layer may be sequentially stacked each other. The third stack layer IL3 may have a structure in which a third hole transport layer, a third organic light emitting layer that emits second light, and a third electron transport layer may be sequentially stacked each other.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining layer PDL, and may be disposed on the bottom surface of each trench TRC. Due to the trench TRC, the first stack layer IL1 may be cut off between adjacent sub-pixels SP1, SP2, and SP3. The second stack layer IL2 may be disposed on the first stack layer IL1. Due to the trench TRC, the second stack layer IL2 may be cut off between adjacent sub-pixels SP1, SP2, and SP3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. For example, in the three-tandem structure, each of the plurality of trenches TRC may be a structure for cutting off the first to second stack layers IL1 and IL2, the first charge generation layer, and the second charge generation layer of the display element layer EML between the sub-pixels SP1, SP2, and SP3 adjacent to each other. In the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent sub-pixels SP1, SP2, and SP3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be disposed on the pixel defining layer PDL.

The number of the stack layers IL1, IL2, and IL3 that emit different lights is not limited to that shown in FIG. 7. For example, the light emitting stack IL may include two intermediate layers. In this case, one of the two intermediate layers may be substantially the same as the first stack layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

FIG. 7 illustrates that the first to third stack layers IL1, IL2, and IL3 are all disposed in the first emission area EA1, the second emission area EA2, and the third emission area EA3, but the embodiment is not limited thereto. For example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic layer TFE1 and TFE2 to prevent oxygen or moisture from permeating into the display element layer EML. For example, the encapsulation layer TFE may include the first encapsulation inorganic layer TFE1, and a second encapsulation inorganic layer TFE2.

The first encapsulation inorganic layer TFE1 may be disposed on the second electrode CAT. The first encapsulation inorganic layer TFE1 may be formed as a multilayer in which one or more inorganic layers selected from silicon nitride (SiNₓ), silicon oxy nitride (SiON), and silicon oxide (SiOₓ) may be alternately stacked each other. The first encapsulation inorganic layer TFE1 may be formed by a chemical vapor deposition (CVD) process.

The second encapsulation inorganic layer TFE2 may be disposed on the first encapsulation inorganic layer TFE1. The second encapsulation inorganic layer TFE2 may be formed of titanium oxide (TiOx) or aluminum oxide (AlOx), but an embodiment is not limited thereto. The second encapsulation inorganic layer TFE2 may be formed by an atomic layer deposition (ALD) process. The thickness of the second encapsulation inorganic layer TFE2 may be smaller than the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, or polyimide resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit first light, for example, light of a blue wavelength band. The blue wavelength band may be in a range of about 370 nm to about 460 nm. Thus, the first color filter CF1 may transmit first light among light emitted from the first emission area EA1.

The second color filter CF2 may overlap the second emission area EA2 of the second sub-pixel SP2. The second color filter CF2 may transmit second light, for example, light of a green wavelength band. The green wavelength band may be in a range of about 480 nm to about 560 nm. Thus, the second color filter CF2 may transmit second light among light emitted from the second emission area EA2.

The third color filter CF3 may overlap the third emission area EA3 of the third sub-pixel SP3. The third color filter CF3 may transmit third light, for example, light of a red wavelength band. The red wavelength band may be in a range of about 600 nm to about 750 nm. Thus, the third color filter CF3 may transmit third light among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a selectable refractive index such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, or polyimide resin.

The cover layer CVL may be disposed on the filling layer FIL. The cover layer CVL may be a glass substrate or a polymer resin. In case that the cover layer CVL is a glass substrate, it may be attached onto the filling layer FIL. In this case, the filling layer FIL may serve to bond the cover layer CVL. In case that the cover layer CVL is a glass substrate, it may serve as an encapsulation substrate. In case that the cover layer CVL is a polymer resin, it may be directly applied onto the filling layer FIL.

The polarizing plate may be disposed on one surface or a surface of the cover layer CVL. The polarizing plate may be a structure for preventing visibility degradation caused by reflection of external light. The polarizing plate may include a linear polarizing plate and a phase retardation film. For example, the phase retardation film may be a λ/4 plate (quarter-wave plate), but the embodiment is not limited thereto. However, in case that visibility degradation caused by reflection of external light is sufficiently overcome by the first to third color filters CF1, CF2, and CF3, the polarizing plate may be omitted.

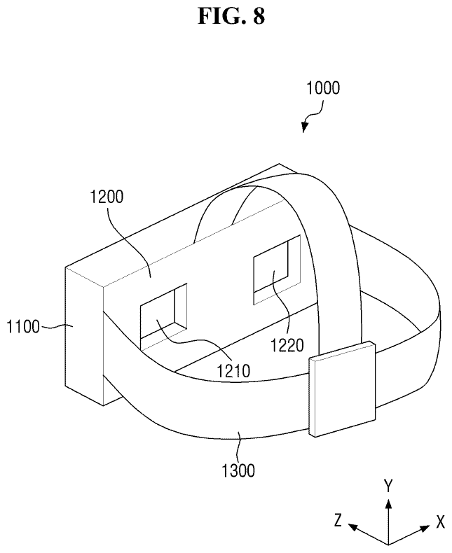

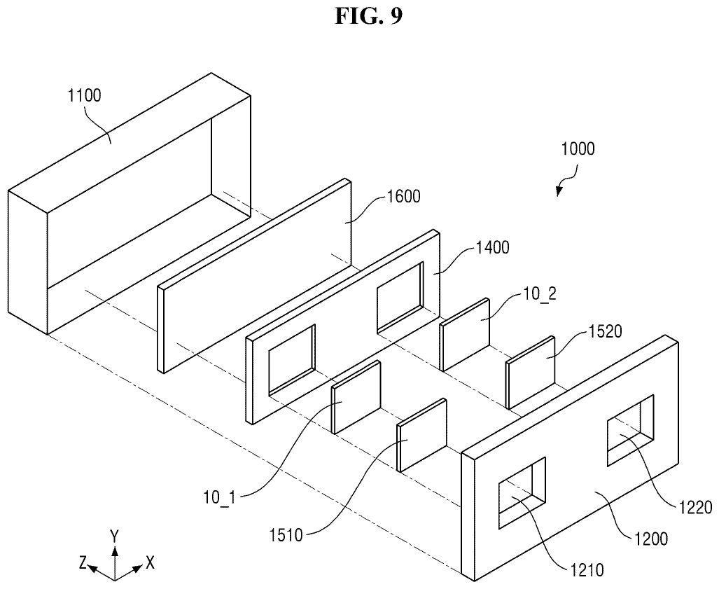

FIG. 8 is a schematic perspective view illustrating a head mounted display according to one embodiment. FIG. 9 is an exploded perspective view illustrating an example of the head mounted display of FIG. 8.

Referring to FIGS. 8 and 9, a head mounted display 1000 according to one embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600 and directions X, Y, Z.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 and 2, a description of the first display device 10_1 and the second display device 10_2 may be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The display device housing 1100 has a horizontal length in a X-axis direction, a vertical length in a Y-axis direction, and a thickness in a Z-axis direction as shown in FIGS. 8 and 9. The control circuit board 1600 may be connected to the first display device 10_1 and the second display device 10_2 through the connector. The control circuit board 1600 may convert an image source inputted from the outside into digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. By way of example, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 8 and 9 illustrate that the first eyepiece 1210 and the second eyepiece 1220 are disposed separately, but the embodiment is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

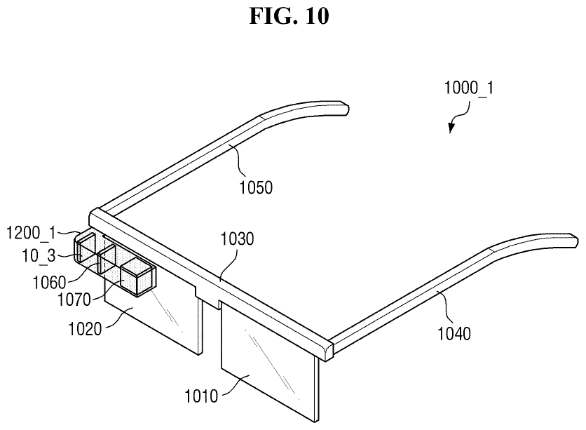

The head mounted band 1300 serves to secure the display device housing 1100 to the user's head such that the first eyepiece 1210 and the second eyepiece 1220 of the housing cover 1200 remain disposed on the user's left and right eyes, respectively. In case that the display device housing 1200 is implemented to be lightweight and compact, the head mounted display 1000 may be provided with, as shown in FIG. 10, an eyeglass frame instead of the head mounted band 1300.

The head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating a head mounted display according to one embodiment.

Referring to FIG. 10, a head mounted display 1000_1 according to one embodiment may be an eyeglasses-type display device in which a display device housing 1200_1 is implemented in a lightweight and compact manner. The head mounted display 1000_1 according to one embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but the embodiment is not limited thereto. For example, the display device housing 1200_1 may be disposed at the left end of the support frame 1030, and in this case, the image of the display device 10_3 may be provided to the user's left eye. By way of example, the display device housing 1200_1 may be disposed at both the left and right ends of the support frame 1030, and in this case, the user may view the image displayed on the display device 10_3 through both the left and right eyes.

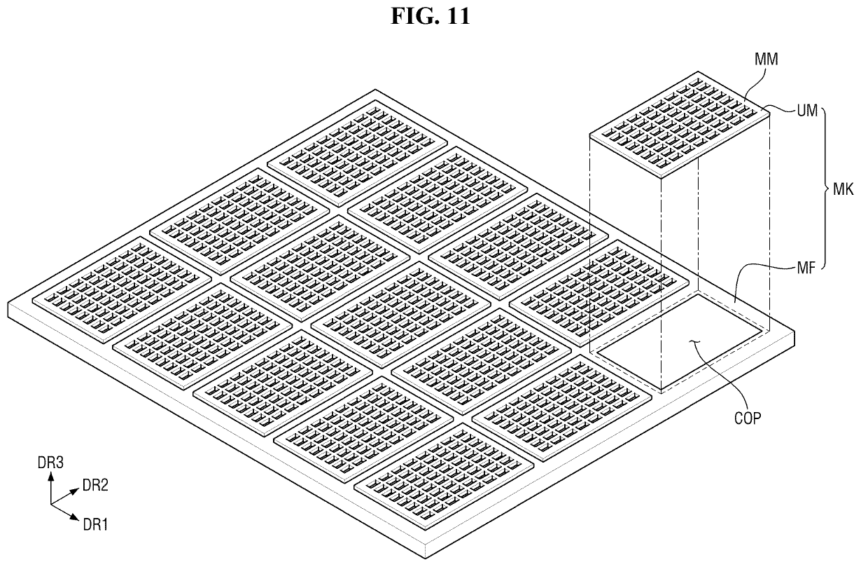

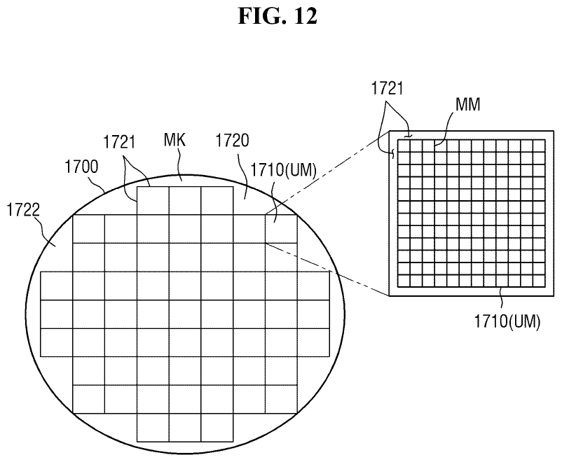

FIG. 11 is a schematic perspective view of a mask according to one embodiment. FIG. 12 is a schematic plan view of a mask according one embodiment. FIG. 11 is a schematic perspective view illustrating a state in which one unit mask UM is separated from a plurality of unit masks. The mask MK according to the embodiment illustrated in FIGS. 11 and 12 may be used in a process of depositing at least a portion of the light emitting stack IL described with reference to FIG. 7. For example, the light emitting stack IL may be configured to emit light of different colors in the sub-pixels SP1 through SP3.

Referring to FIGS. 11 and 12, the mask MK according to the embodiment may be a shadow mask in which mask membranes MM are disposed on a silicon substrate 1700. The mask MK according to the embodiment may be referred to as a “silicon mask.”

According to an embodiment, the mask MK may include the silicon substrate 1700, and the mask membranes MM may be disposed on the silicon substrate 1700. The mask membranes MM may be respectively disposed in cell areas 1710 arranged or disposed in a matrix form, and each cell area 1710 may be surrounded by a mask rib area 1721. The mask rib area 1721 may support the mask membranes MM.

A mask membrane MM may be a part of a unit mask UM disposed in each of the cell areas 1710.

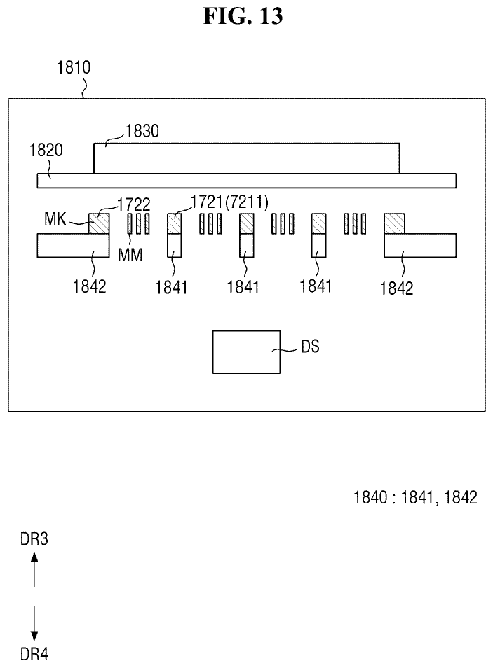

The silicon substrate 1700 may include a plurality of cell areas 1710 and a mask frame area 1720 excluding the cell areas 1710. The mask frame area 1720 may include the mask rib area 1721 surrounding each cell area 1710 and an outer frame area 1722 disposed at an outermost periphery of the silicon substrate 1700. A mask frame MF may be disposed in the mask frame area 1720. The mask frame MF may include mask ribs 7211 (see FIG. 13) surrounding the cell areas 1710.

The mask rib area 1721 may be an area that separates the cell areas 1710. For example, the cell areas 1710 may be arranged or disposed in a matrix form, and the mask ribs 7211 (see FIG. 13) disposed in the mask rib area 1721 may surround the outside of the mask membrane MM disposed in each of the cell areas 1710.

A cell opening COP and a unit mask UM that masks at least a portion of the cell opening COP may be disposed in each of the cell areas 1710 of the silicon substrate 1700.

A plurality of cell openings COP may penetrate the mask frame MF along the thickness direction (for example, the third direction DR3) of the mask MK. The cell openings COP may be formed by partially etching the silicon substrate 1700 from a back side.

Each unit mask UM may include a mask membrane MM, and the mask membrane MM may include mask openings.

The mask openings of each mask membrane MM may be referred to as “holes” or “mask holes”. The mask openings may penetrate the unit masks UM along the thickness direction (for example, the third direction DR3) of the mask MK.

One unit mask UM can be used in a deposition process of one display panel 100. In the disclosure, the term “unit mask UM” can be replaced with a term such as “mask unit UM”.

FIG. 13 is a configuration view of a deposition equipment according to one embodiment.

Referring to FIG. 13, a deposition equipment according to one embodiment may include a chamber 1810, a deposition source DS disposed inside the chamber 1810, a mask MK disposed between a first substrate 1820 and the deposition source DS inside the chamber 1810, and a mask support 1840 disposed between the deposition source DS and the mask MK to support at least a portion of the mask MK.

According to one embodiment, the mask MK may include a second substrate 1700 including a plurality of cell areas 1710 and a mask frame area 1720 excluding the plurality of cell areas 1710, and a mask membrane MM disposed at each cell area 1710, and the cross-sectional structure of a mask membrane MM may be configured as a multilayer in which a plurality of inorganic layers and a plurality of metal layers may be alternately stacked each other, or as a mixed layer in which at least one inorganic material and at least one metal are mixed.

The first substrate 1820 shown in FIG. 13 may be a display panel 100 described with reference to FIGS. 1 to 10. Accordingly, the description in relation to the first substrate 1820 will be replaced with description of the display panel 100 with reference to FIGS. 1 to 10.

A second substrate 1700 shown in FIG. 13 may be the silicon substrate 1700 described with reference to FIGS. 11 to 12. Accordingly, the description of the second substrate 1700 will be replaced with the description of the silicon substrate 1700 with reference to FIGS. 11 to 12.

The mask support 1840 may serve to support and secure the mask MK at the bottom of the mask MK. For example, the mask support 1840 may be comprised of an electrostatic chuck. According to one embodiment, the mask support 1840 may include a first support area 1841 that supports a mask rib area 1721, and a second support area 1842 that supports an outer frame area 1722. However, the mask support 1840 may not support the mask rib area 1721, and for example, the first support area 1841 may be omitted.

1830 shown in FIG. 13 is a fixing member that fixes the first substrate 1820, and for example, may be configured as an electrostatic chuck.

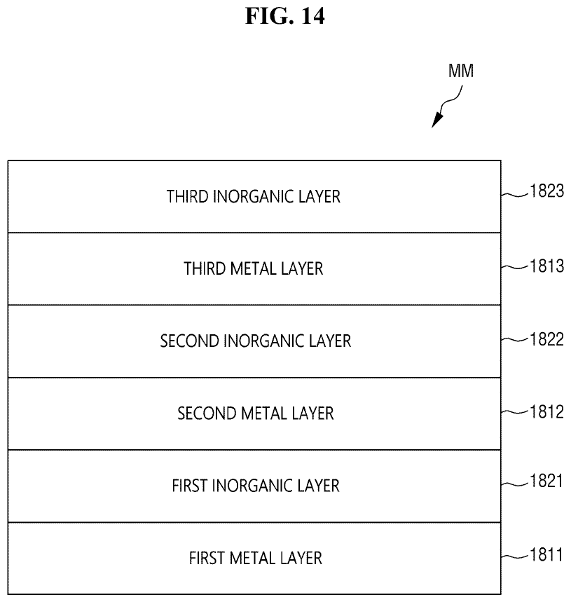

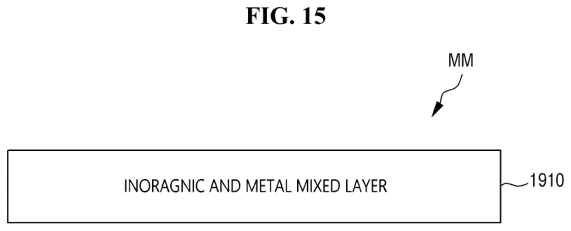

In the deposition equipment according to one embodiment, the mask membrane MM of the mask MK is configured as a multilayer in which a plurality of inorganic layers and a plurality of metal layers may be alternately stacked each other, or as a mixed layer in which at least one inorganic material and at least one metal are mixed. Such stacked structure of the mask membrane MM will be described in detail in conjunction with FIGS. 14 to 15.

FIG. 14 is a drawing illustrating a stacked structure of a mask membrane MM according to one embodiment. For example, the mask membrane MM illustrated in FIG. 14 is configured as a multilayer in which a plurality of inorganic layers and a plurality of metal layers may be alternately stacked each other.

According to one embodiment, the cross-sectional structure of the mask membrane MM may include a first metal layer 1811, a first inorganic layer 1821 disposed on the first metal layer 1811, a second metal layer 1812 disposed on the first inorganic layer 1821, a second inorganic layer 1822 disposed on the second metal layer 1812, a third metal layer 1813 disposed on the second inorganic layer 1822, and a third inorganic layer 1823 disposed on the third metal layer 1813.

In the illustrated example, the first to third inorganic layers 1821, 1822, and 1823 are described as the plurality of inorganic layers, but the number of the layers including the inorganic layers are not limited thereto.

In the illustrated example, the first to third metal layers 1811, 1812, and 1813 are described as the plurality of metal layers, but the number of the layers including the metal layers are not limited thereto.

Although not illustrated, according to one embodiment, the cross-sectional structure of the mask membrane MM may include a multilayer including two inorganic layers and three metal layers. In this case, the inorganic layers and metal layers may be alternately stacked each other.

Although not illustrated, according to one embodiment, the cross-sectional structure of the mask membrane MM may include a multilayer including three inorganic layers and two metal layers. In this case, the inorganic layers and metal layers may be alternately stacked each other.

Although not illustrated, according to one embodiment, the cross-sectional structure of the mask membrane MM may include a multilayer including two inorganic layers and two metal layers. In this case, the inorganic layers and metal layers may be alternately stacked each other.

Although not illustrated, according to one embodiment, the cross-sectional structure of the mask membrane MM may include a multilayer including one or more inorganic layers and one or more metal layers. For example, the mask membrane MM may include one inorganic layer and one metal layer. By way of example, the mask membrane MM may include one inorganic layer and two metal layers. By way of example, the mask membrane MM may include two inorganic layers and one metal layer. According to one embodiment, when viewed from a cross-section in which the mask membrane MM is cut, the first metal layer 1811 is disposed on the lowermost layer of the mask membrane MM and the third inorganic layer 1823 is disposed on the uppermost layer.

According to one embodiment, the first inorganic layer 1821 may include at least one selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

According to one embodiment, the second inorganic layer 1822 may include at least one selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

According to one embodiment, the third inorganic layer 1823 may include at least one selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

According to one embodiment, the materials of the first to third inorganic layers 1821, 1822, and 1823 may be the same.

According to one embodiment, the materials of the first to third inorganic layers 1821, 1822, and 1823 may be different. For example, at least two layers selected from the first to third inorganic layers 1821, 1822, and 1823 may include inorganic layers of different materials.

According to one embodiment, the first metal layer 1811 may include at least one material from copper (Cu), nickel (Ni), aluminum (Al), tungsten (W), molybdenum (Mo), titanium (Ti), and invar.

According to one embodiment, the second metal layer 1812 may include at least one material from copper (Cu), nickel (Ni), aluminum (Al), tungsten (W), molybdenum (Mo), titanium (Ti), and invar.

According to one embodiment, the third metal layer 1813 may include at least one material from copper (Cu), nickel (Ni), aluminum (Al), tungsten (W), molybdenum (Mo), titanium (Ti), and invar.

According to one embodiment, the materials of the first to third metal layers 1811, 1812, and 1813 may be the same.

According to one embodiment, the materials of the first to third metal layers 1811, 1812, and 1813 may be different. For example, at least two layers selected from the first to third metal layers 1811, 1812, and 1813 may include metal layers of different materials.

FIG. 15 is a drawing illustrating a stacked structure of a mask membrane MM according to one embodiment. For example, the mask membrane MM is configured as a mixed layer 1910 in which at least one inorganic layer and at least one metal layer are mixed.

The mixed layer 1910 according to one embodiment may include a mixed material in which at least one inorganic material selected from silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ) and at least one metal material from copper (Cu), nickel (Ni), aluminum (Al), tungsten (W), molybdenum (Mo), titanium (Ti), and invar are mixed.

According to one embodiment, in forming the mixed layer 1910, processes such as chemical vapor deposition (CVD), atomic layer deposition (ALD), and sputtering may be used.

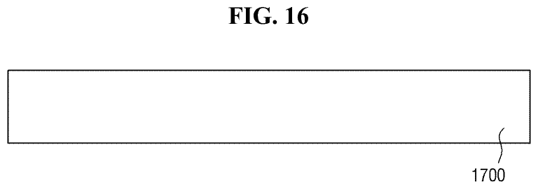

FIGS. 16 to 20 are process cross-sectional views illustrating a method for manufacturing a mask according to one embodiment. For example, FIGS. 16 to 20 may be examples illustrating a method for manufacturing a mask including the mask membrane illustrated in FIG. 14.

A method for manufacturing the mask including the mask membrane illustrated in FIG. 14 will be described with reference to FIGS. 16 to 20.

Referring to FIG. 16, a silicon substrate 1700 may be prepared. As described with reference to FIG. 12, the silicon substrate 1700 may include a plurality of cell areas 1710 and a mask frame area 1720 excluding the cell areas 1710. The mask frame area 1720 may include the mask rib area 1721 surrounding each cell area 1710 and an outer frame area 1722 disposed at an outermost periphery of the silicon substrate 1700.

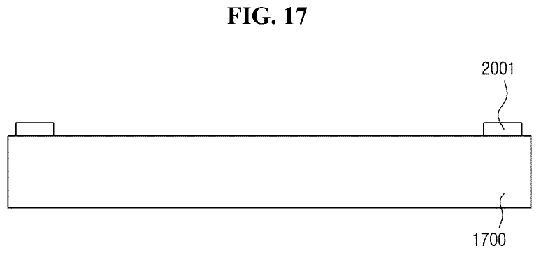

Referring to FIG. 17, an align key 2001 may be formed in a portion of the mask frame area 1720 of the silicon substrate 1700. For example, the align key 2001 may be formed by depositing an inorganic layer or a metal layer on the silicon substrate 1700 and patterning the deposited inorganic layer or metal layer. In the disclosure, the material of the align key 2001 is not limited.

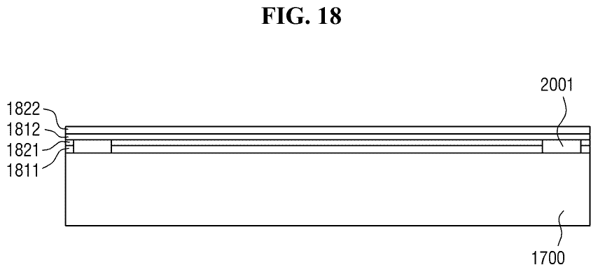

Referring to FIG. 18, multilayers for the mask membrane MM may be sequentially stacked on the silicon substrate 1700 on which the align key 2001 is formed. For example, the mask membrane MM is configured as a multilayer in which a plurality of inorganic layers and a plurality of metal layers may be alternately stacked each other. Although the first metal layer 1811, the first inorganic layer 1821 disposed on the first metal layer 1811, the second metal layer 1812 disposed on the first inorganic layer 1821, and the second inorganic layer 1822 disposed on the second metal layer 1812 are illustrated as an example of the multilayer in FIG. 18, the disclosure is not limited thereto.

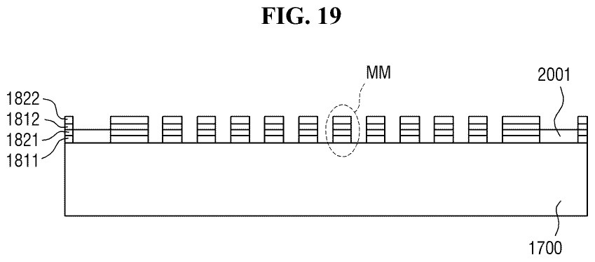

Referring to FIG. 19, the multilayer stacked on the silicon substrate 1700, for example, the first metal layer 1811, the first inorganic layer 1821 disposed on the first metal layer 1811, the second metal layer 1812 disposed on the first inorganic layer 1821, and the second inorganic layer 1822 disposed on the second metal layer 1812 are patterned to form a mask membrane MM. The mask membrane MM may form an opening exposing the bottom surface of the silicon substrate 1700 in each cell area 1710 during the process.

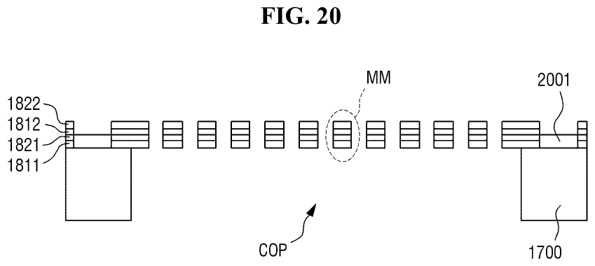

Referring to FIG. 20, a cell opening COP is formed by etching the rear surface of the silicon substrate 1700 corresponding to the cell area 1710. The cell opening COP may expose the rear surface of the mask membrane MM in the cell area 1710.

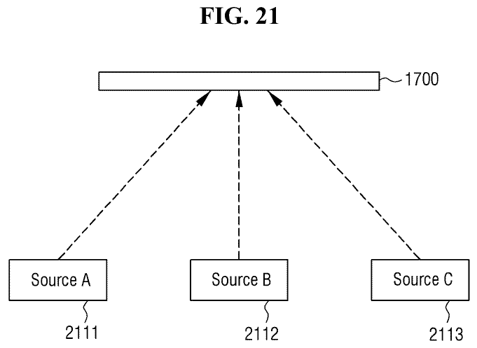

FIGS. 21 to 25 are diagrams illustrating a method of forming a mask membrane as a mixed layer according to one embodiment. Each of FIGS. 21 to 25 may be an example illustrating a method for manufacturing a mask including the mask membrane illustrated in FIG. 15. For example, the method of depositing a mixed layer described with reference to each of FIGS. 21 to 25 may be performed instead of the deposition process of the multilayer illustrated in FIG. 18.

Hereinafter, the mask membrane illustrated in FIG. 15 will be described with reference to FIGS. 21 to 25.

Referring to FIG. 21, a mixed layer configuring a membrane MM according to one embodiment may be formed by moving a silicon substrate 1700 to a chamber equipped with a first deposition material 2111, a second deposition material 2112, and a third deposition material 2113, and evaporating the first deposition material 2111, the second deposition material 2112, and the third deposition material 2113. For example, the mixed layer may be a three-type layer in which three types of materials are mixed by simultaneously depositing the first deposition material 2111, the second deposition material 2112, and the third deposition material 2113. At this time, in case that evaporating each of the first deposition material 2111, the second deposition material 2112, and the third deposition material 2113, the ratio of materials included in the mixed layer may be adjusted by adjusting the power for evaporating each material.

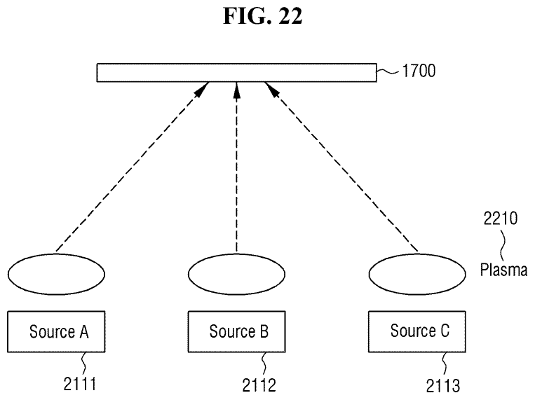

Referring to FIG. 22, a mixed layer configuring a mask membrane MM according to one embodiment may be formed by moving a silicon substrate 1700 to a chamber equipped with a first deposition material 2111, a second deposition material 2112, and a third deposition material 2113, and generating a plasma 2210 in the first deposition material 2111, the second deposition material 2112, and the third deposition material 2113. At this time, the ratio of materials included in the mixed layer may be adjusted by adjusting the power of the plasma 2210 in respect to each material.

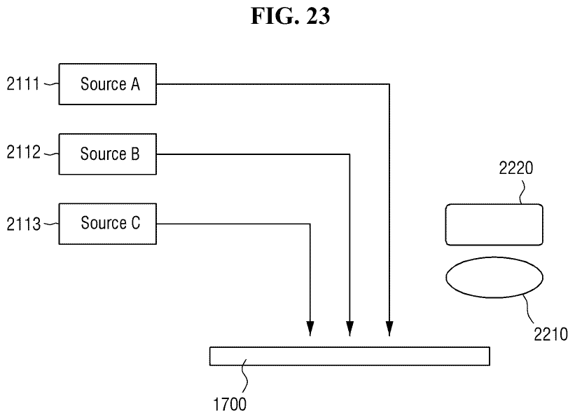

Referring to FIG. 23, a mixed layer configuring a mask membrane MM according to one embodiment may be formed by moving a silicon substrate 1700 to a chamber equipped with a first deposition material 2111, a second deposition material 2112, and a third deposition material 2113, injected with three different gases, and using a plasma 2210 or heat 2220 to generate a gas reaction. At this time, the ratio of materials included in the mixed layer may be adjusted by adjusting the ratio of gas of each material inside the chamber.

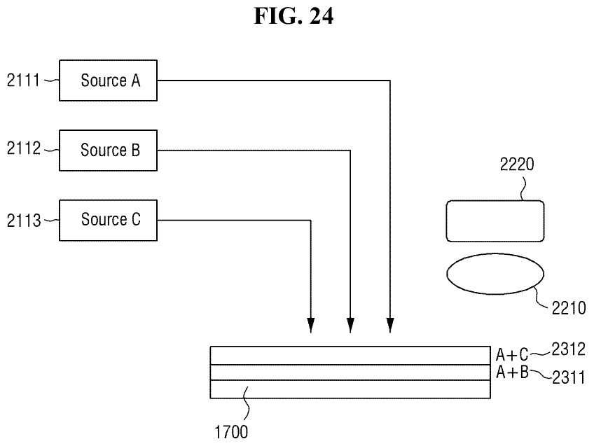

Referring to FIG. 24, a mixed layer configuring a mask membrane MM according to one embodiment may include a first mixed layer 2311 in which a first deposition material 2111 and a second deposition material 2112 are mixed and a second mixed layer 2312 in which the first deposition material 2111 and a third deposition material 2113 are mixed and deposited on the first mixed layer 2311. First, in order to form the first mixed layer 2311, a silicon substrate 1700 may be moved to a chamber into which two different gases including the first deposition material 2111 and the second deposition material 2112 are injected, and a gas reaction may be generated using heat 2220 or a plasma 2210. Subsequently, in order to form the second mixed layer 2312 on the first mixed layer 2311, the silicon substrate 1700 may be moved to the chamber into which two different gases including the first deposition material 2111 and the third deposition material 2113 are injected, and a gas reaction may be generated using the heat 2220 or plasma 2210.

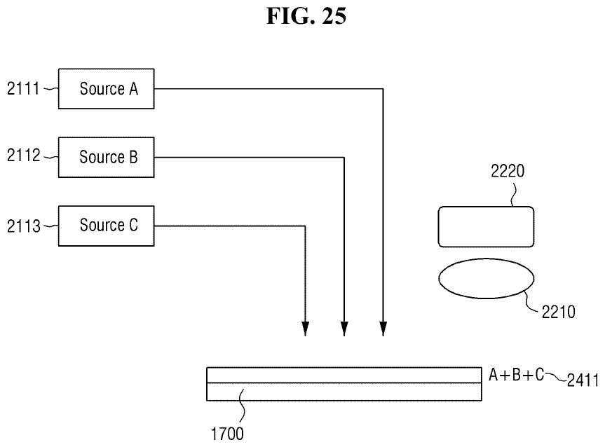

In the embodiment of FIG. 25, unlike in the embodiment of FIG. 24, in case that applying three different gases including the first deposition material 2111, the second deposition material 2112, and the third deposition material 2113, the third gas of the third deposition material 2113 which is a reactant gas may be injected after injecting the first gas of the first deposition material 2111 and the second gas of the second deposition material 2112, which is a source gas, thereby forming a mixed layer 2411. At this time, the ratio of materials included in a mixed layer 2411 may be adjusted by adjusting the ratio of the first gas and the second gas inside the chamber. According to embodiments, it is possible for a deposition mask and a deposition equipment including the same to have high mechanical strength and be readily cleaned, and increase the accuracy of the alignment by reducing coefficient of thermal expansion (CTE).

According to embodiments, it is also possible for a deposition mask and a deposition equipment to reduce deposition defects due to deviation in the thickness of the mask.

The above description is an example of technical features of the disclosure, and those skilled in the art to which the disclosure pertains will be able to make various modifications and variations. Therefore, the embodiments of the disclosure described above may be implemented separately or in combination with each other.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A deposition mask comprising:
a substrate comprising a plurality of cell areas and a mask frame area excluding the plurality of cell areas; and
a mask membrane disposed in each of the plurality of cell areas,
wherein a cross-sectional structure of the mask membrane includes a multilayer in which a plurality of inorganic layers and a plurality of metal layers are alternately stacked each other.

2. The deposition mask of claim 1, wherein a cross-sectional structure of the mask membrane comprises:
a first metal layer;
a first inorganic layer disposed on the first metal layer;
a second metal layer disposed on the first inorganic layer;
a second inorganic layer disposed on the second metal layer;
a third metal layer disposed on the second inorganic layer; and
a third inorganic layer disposed on the third metal layer.

3. The deposition mask of claim 2, wherein, when viewed from a cross-section in which the mask membrane is cut, the first metal layer is disposed on a lowermost layer of the mask membrane and the third inorganic layer is disposed on an uppermost layer of the mask membrane.

4. The deposition mask of claim 2, wherein the first inorganic layer includes at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

5. The deposition mask of claim 4, wherein the second inorganic layer includes at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

6. The deposition mask of claim 5, wherein the third inorganic layer includes at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ).

7. The deposition mask of claim 6, wherein materials of the first inorganic layer, the second inorganic layer and the third inorganic layer are same.

8. The deposition mask of claim 6, wherein materials of the first inorganic layer, the second inorganic layer and the third inorganic layer are different from each other.

9. The deposition mask of claim 2, wherein the first metal layer includes at least one material of copper (Cu), nickel (Ni), aluminum (Al), tungsten (W), molybdenum (Mo), titanium (Ti), and invar.

10. The deposition mask of claim 9, wherein the second metal layer includes at least one material of copper (Cu), nickel (Ni), aluminum (Al), tungsten (W), molybdenum (Mo), titanium (Ti), and invar.

11. The deposition mask of claim 10, wherein the third metal layer includes at least one material of copper (Cu), nickel (Ni), aluminum (Al), tungsten (W), molybdenum (Mo), titanium (Ti), and invar.

12. The deposition mask of claim 11, wherein the materials of the first metal layer, the second metal layer and the third metal layer are same.

13. The deposition mask of claim 11, wherein the materials of the first metal layer, the second metal layer and the third metal layer are different from each other.

14. A deposition mask comprising:
a substrate comprising a plurality of cell areas and a mask frame area excluding the plurality of cell areas; and
a mask membrane disposed in each of the plurality of cell areas,
wherein the mask membrane comprises a mixed layer in which at least one inorganic layer and at least one metal layer are mixed.

15. The deposition mask of claim 14, wherein the mixed layer includes a mixed material in which at least one inorganic material of silicon (Si), silicon nitride (SiNₓ), silicon oxynitride (SiON), silicon oxide (SiOₓ), titanium oxide (TiOₓ), amorphous silicon (a-Si), and aluminum oxide, and at least one metal material of copper (Cu), nickel (Ni), aluminum (Al), tungsten (W), molybdenum (Mo), titanium (Ti), and invar are mixed.

16. The deposition mask of claim 15, wherein the substrate is a silicon substrate.

17. A deposition equipment comprising:
a chamber;
a deposition source disposed in the chamber;
a mask disposed between a first substrate and the deposition source in the chamber; and
a mask support disposed between the deposition source and the mask to support at least a portion of the mask, wherein
the mask comprises:
a second substrate including a plurality of cell areas and a mask frame excluding the plurality of cell areas; and
a mask membrane disposed in each of the plurality of cell areas, and
a cross-sectional structure of the mask membrane includes a multilayer in which a plurality of inorganic layers and a plurality of metal layers are alternately stacked each other.

18. The deposition equipment of claim 17, wherein the cross-sectional structure of the mask membrane comprises:
a first metal layer;
a first inorganic layer disposed on the first metal layer;
a second metal layer disposed on the first inorganic layer;
a second inorganic layer disposed on the second metal layer;
a third metal layer disposed on the second inorganic layer; and
a third inorganic layer disposed on the third metal layer.

19. The deposition equipment of claim 18, wherein, when viewed from a cross-section in which the mask membrane is cut, the first metal layer is disposed on a lowermost layer of the mask membrane and the third inorganic layer is disposed on an uppermost layer of the mask membrane.

20. The deposition equipment of claim 19, wherein
the first inorganic layer, the second inorganic layer and the third inorganic layer include at least one of silicon (Si), silicon nitride (SiNₓ), silicon oxynitride (SiON), silicon oxide (SiOₓ), titanium oxide (TiOₓ), amorphous silicon (a-Si), and aluminum oxide (AlOₓ), and
the first metal layer, the second metal layer and the third metal layer include at least one material of copper (Cu), nickel (Ni), aluminum (Al), tungsten (W), molybdenum (Mo), titanium (Ti), and invar.
